(19) United States
(12) Patent Application Publication
(10) Pub. No.: US 2025/0234559 A1
(43) Pub. Date: Jul. 17, 2025

(54) SEMICONDUCTOR STRUCTURE HAVING NON-SILICIDE SOURCE/DRAIN CONTACT AND METHOD FOR MANUFACTURING THE SAME

(71) Applicant: TAIWAN SEMICONDUCTOR MANUFACTURING COMPANY, LTD., Hsinchu (TW)

(72) Inventors: Ching-Tzer WENG, Hsinchu (TW); Chi-Wei HO, Hsinchu (TW); Kao-Chao LIN, Hsinchu (TW); Yu-Ting TSAI, Hsinchu (TW); Chia-Ta HSIEH, Hsinchu (TW)

(73) Assignee: TAIWAN SEMICONDUCTOR MANUFACTURING COMPANY, LTD., Hsinchu (TW)

(21) Appl. No.: 18/410,303

(22) Filed: Jan. 11, 2024

(51) Int. Cl. H10B 63/00; H01L 21/28; H01L 29/49

(52) U.S. Cl. CPC H10B 63/30; H01L 21/28052; H10D 64/663

(57) ABSTRACT

A method for manufacturing semiconductor structure includes: forming a gate structure on a substrate; forming a source portion and a drain portion in the substrate respectively at two opposite sides of the gate structure; forming a protection layer over the substrate, the gate structure, the source portion and the drain portion; forming an opening in the protective layer to expose the gate structure; and performing a silicidation process to form a silicide layer on the exposed gate structure.

### BACKGROUND

A logic device, such as a transistor, is connected to a memory device (e.g., a resistive random-access memory (RRAM)), so as to control and drive the RRAM. That is, performance of the transistor contributes to the performance of the RRAM. Therefore, with advancement of technology, enhancement in process flow and/or structure of the transistor is continuously required to improve reliability of both the transistor and the RRAM connected to the transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 18 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including a transistor and a memory device (e.g., a resistive random-access memory (RRAM)) connected to the transistor, and a method for manufacturing the same. The transistor includes a source portion, a drain portion, and a gate structure having a gate electrode. The gate electrode is connected to a gate contact through a silicide layer. The source portion and the drain portion are respectively, and directly, connected to a source contact and a drain contact. The RRAM is connected to the transistor through the drain contact. It is noted that, in accordance with some embodiments of the present disclosure, the silicide layer formed between the gate contact and the gate electrode, is absent between the source contact and the source portion, and also absent between the drain contact and the drain portion. Such absence of silicide layer at the source portion and/or the drain portion is known as a non-silicide contact which significantly suppresses current leakage between the source portion and the drain portion, and avoids silicide piping (when such silicide layer is present). In addition, since silicide piping is obviated, adjacent ones of RRAMs and/or transistors may be more densely packed.

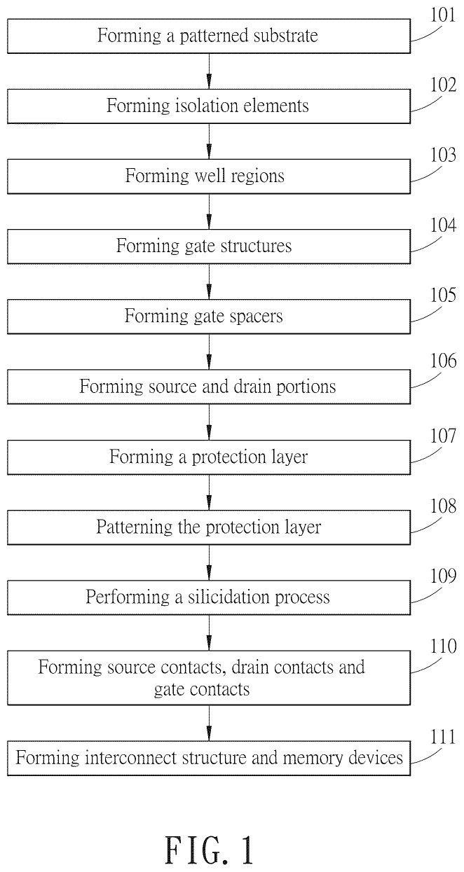

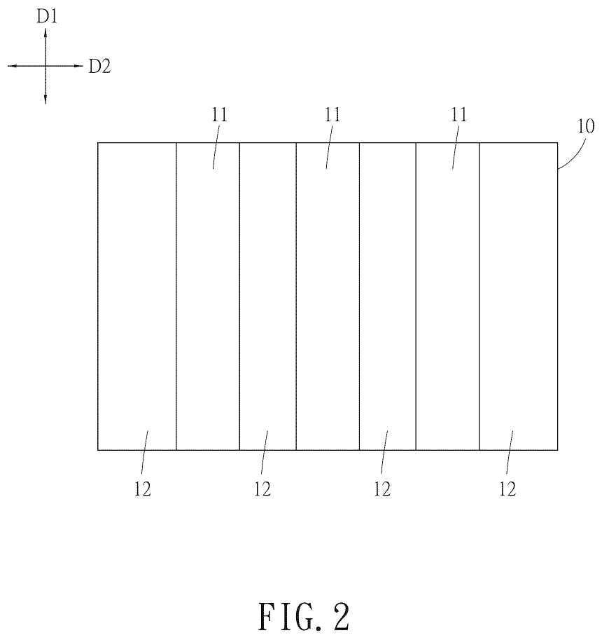

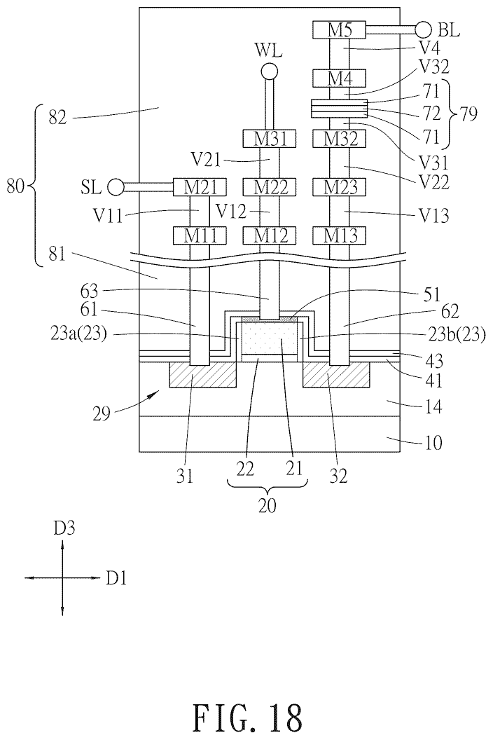

FIG. 1 is a flow diagram illustrating a method for manufacturing the semiconductor structure (for example, the semiconductor structure shown in FIG. 18) in accordance with some embodiments. FIGS. 2 to 18 illustrate schematic views of intermediate stages of the method in accordance with some embodiments. Some repeating structures are omitted in FIGS. 2 to 18 for the sake of brevity. Additional steps can be provided before, after or during the method, and some of the steps described herein may be replaced by other steps or be eliminated.

Referring to FIG. 1 and the example illustrated in FIG. 2, the method begins at step 101, where a patterned substrate 10 is formed to have a plurality of active regions (also known as ODs) 11 and trenches 12. FIG. 2 is a schematic top view of a resultant structure of step 101.

In a patterning process for forming the patterned substrate 10, any suitable etching processes (e.g., dry etching, but is not limited thereto) may be adopted to remove portions of an upper part of a starting substrate (not shown), thereby forming the trenches 12 and the active regions 11. Each of the trenches 12 extends from an upper surface of the patterned substrate 10 to an interior of the patterned substrate 10. In some embodiments, as shown in FIG. 2, each of the trenches 12 and the active regions 11 elongates along a first direction (D1). Number of the active regions 11 and/or number of the trenches 12 may be determined according to practical needs. As shown in FIG. 2, in some embodiments, there are three active regions 11 and four trenches 12. In some embodiments, before the patterning process, a photoresist (not shown) may be formed over the starting substrate to serve as a patterning mask (not shown) for the patterning process, and the photoresist may be removed after the patterning process.

In some embodiments, the starting substrate for forming the patterned substrate 10 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The starting substrate may be doped with p-type impurities or n-type impurities, or undoped. In addition, the starting substrate for forming the patterned substrate 10 may be a bulk silicon substrate, a silicon-on-insulator (SOI) substrate, or a germanium-on-insulator (GOI) substrate. In some embodiments, the starting substrate may be made of silicon. Other suitable materials for forming the patterned substrate 10 are within the contemplated scope of disclosure.

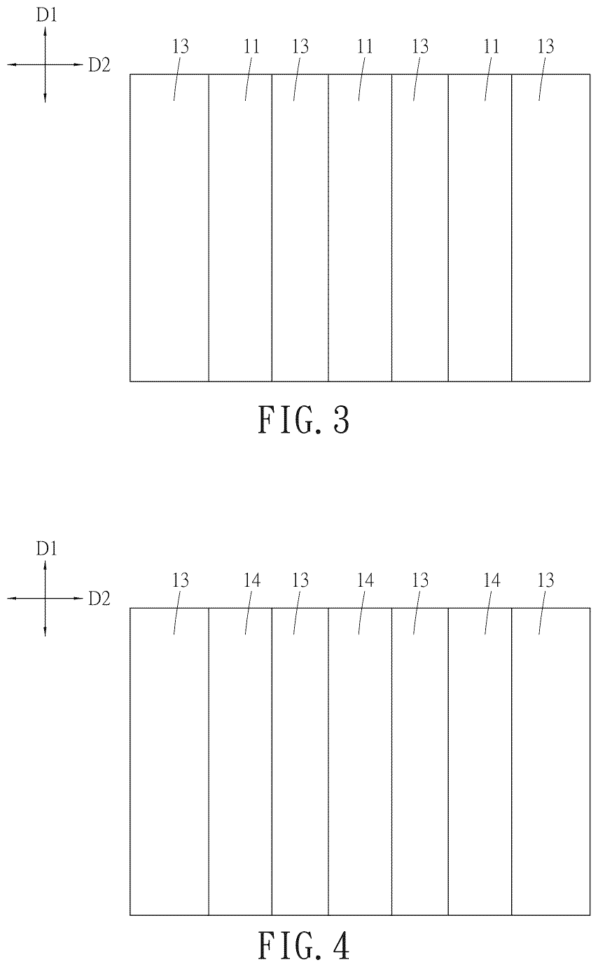

Referring to FIG. 1 and the example illustrated in FIGS. 2 and 3, the method proceeds to step 102, where isolation elements 13 are formed to respectively fill the trenches 12. FIG. 3 is a schematic top view of a resultant structure of step 102.

In some embodiments, step 102 may include filling the trenches 12 with an isolation material using a deposition process, followed by a planarization processes to remove an excess amount of the isolation material and to expose the active regions 11, thereby forming the isolation elements 13. The isolation elements 13 may serve as shallow trench isolation (STI) features. The deposition processes may include chemical vapour deposition (CVD), atomic layer deposition process (ALD), physical vapour deposition (PVD), combinations thereof, or other suitable processes, and the planarization processes may include chemical mechanical polishing (CMP) processes or other suitable processes.

In some embodiments, the isolation material may include an oxide material, such as silicon oxide, but is not limited thereto. Other materials and processes suitable for forming the isolation elements 13 are within the contemplated scope of the present disclosure.

Referring to FIG. 1 and the example illustrated in FIGS. 3 and 4, the method proceeds to step 103, where well regions 14 are respectively formed in the active regions 11. FIG. 4 is a schematic top view of a resultant structure of step 103.

In some embodiments, the well regions 14 are each formed occupying an entire of a respective one of the active regions 11, i.e., each of the well regions 14 elongates along the first direction (D1).

In some embodiment, the well regions 14 have a first conductivity type, which may be determined according to practical needs. For instance, when transistors 29 (see FIG. 18, one of which is shown) in the semiconductor structure are designed to be NMOS transistors, the well regions 14 may be p-type. Vice versa, when the transistors 29 are designed to be PMOS transistors, the well regions 14 may be n-type.

In certain embodiments, the well regions 14 are formed by subjecting the active regions 11 to a first ion implantation process. Each of the well regions 14 extends from a top surface of a respective active region 11 into an interior of the respective active region 11. In some embodiments, the isolation elements 13 may also be subjected to the first ion implantation process, but the isolation elements 13 still retain electrical isolation property thereof. P-type dopants, such as boron, may be implanted to form p-type well regions 14. N-type dopants, such as phosphorus, arsenic, may be implanted to form n-type well regions 14. In some embodiments, the well regions 14 are p-type well regions. Amount of dopants may be determined according to practical needs. Other suitable materials and/or processes for forming the well regions 14 are within the contemplated scope of the present disclosure.

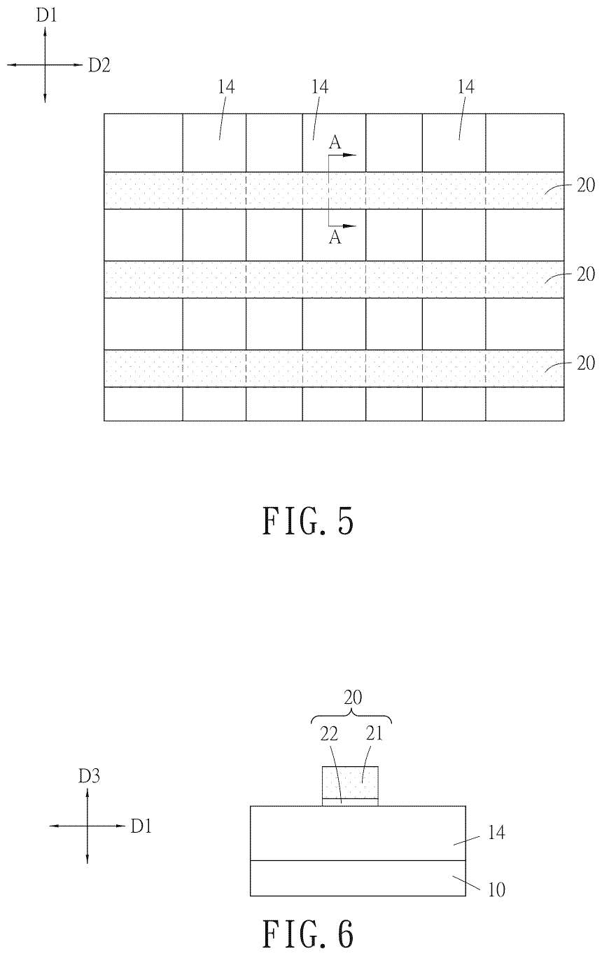

Referring to FIG. 1 and the example illustrated in FIGS. 5 and 6, the method proceeds to step 104, where gate structures 20 are formed on the well regions 14. FIG. 5 is a schematic top view of a resultant structure of step 104. FIG. 6 is a cross-sectional view taken along line A-A shown in FIG. 5.

Number of the gate structures 20 may be determined according to practical needs. As shown in FIG. 5, in some embodiments, there are three gate structures 20 that are spaced apart from each other along the first direction (D1). Each of the gate structures 20 may elongate along a second direction (D2) transverse to (e.g., perpendicular to) the first direction (D1).

As shown in FIGS. 5 and 6, each of the gate structures 20 (one of which is shown in FIG. 6) includes a gate electrode 21, and a gate dielectric 22 disposed to separate the gate electrode 21 from the well regions 14. For instance, the gate electrode 21 is disposed on the gate dielectric 22 opposite to the well regions 14 in a third direction (D3), which is transverse (e.g., perpendicular to) both the first direction (D1) and the second direction (D2).

In some embodiments, the gate electrode 21 may be made of polysilicon, and the gate dielectric 22 may be made of a dielectric material, such as silicon oxide or a high dielectric constant (high k) material (e.g., hafnium oxide). Other suitable materials and/or configurations for the gate electrode 21 and the gate dielectric 22 are within the contemplated scope of the present disclosure. In some embodiments, the gate structures 20 may be formed by conformally forming a gate dielectric material and a gate electrode material over the structure shown in FIG. 4 using a deposition process, followed by a patterning process. Other suitable materials and/or processes for forming the gate structures 20 are within the contemplated scope of the present disclosure. The deposition processes may include chemical vapour deposition (CVD), atomic layer deposition process (ALD), physical vapour deposition (PVD), combinations thereof, or other suitable processes, and the patterning processes may include photolithography processes involving etching processes (e.g., wet etching, dry etching), or other suitable processes.

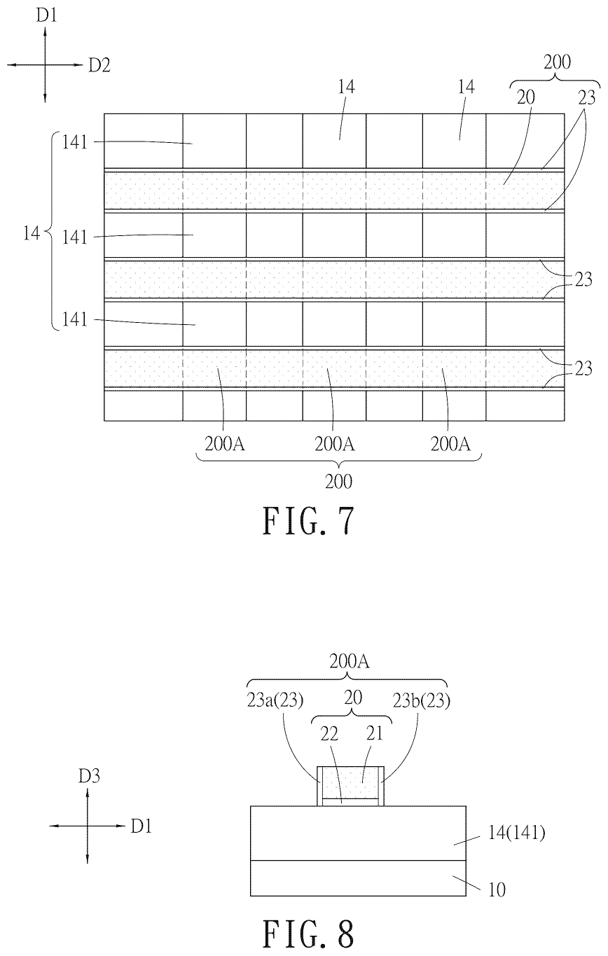

Referring to FIG. 1 and the example illustrated in FIGS. 7 and 8, the method proceeds to step 105, where gate spacers 23 are formed at opposite sidewalls of the gate structures 20. FIG. 7 is a schematic top view of a resultant structure of step 105. FIG. 8 is a cross-sectional view of the resultant structure of step 105 (subsequent to that shown in FIG. 6).

For instance, as shown in FIG. 8, for each of the gate structures 20, two of the gate spacers 23 (e.g., 23a, 23b) are respectively formed covering two opposite sidewalls of the gate structure 20 (i.e., sidewalls of the respective gate electrode 21 and the respective gate dielectric 22) along the first direction (D1). As such, each of the gate structures 20, and the two respective gate spacers 23 (e.g., 23a, 23b) cover a portion of each of the well regions 14, and expose two other portions of each of the well regions 14 at two opposite sides of each of the gate structures 20 along the first direction (D1).

In some embodiments, the gate spacers 23 may include a dielectric material (such as silicon oxide, silicon nitride, or a combination thereof), or any other suitable materials. The gate spacers 23 may be a single-layer structure or a multi-layered structure, and may be formed by conformal depositing a gate spacer material over the structure shown in FIG. 5, followed by an anisotropic etching process to remove an excess amount of the gate spacer material so as to expose at least top surfaces of the gate structures 20, the well regions 14 and the isolation elements 13. Other suitable materials and/or processes for forming the gate spacers 23 are within the contemplated scope of the present disclosure.

After step 105, a plurality of gate units 200 are obtained. The gate units 200 are spaced apart from each other along the first direction (D1). Each of the gate units 200 includes one of the gate structures 20, and two corresponding ones of the gate spacers 23 sandwiching the corresponding gate structure 20 along the first direction (D1). In addition, each of the gate units 200 includes a plurality of gate parts 200A displaced from each other in the second direction (D2), and each of the well regions 14 has a plurality of well areas 141 displaced from each other in the first direction (D1). Each of the gate parts 200A partially covers a corresponding one of the well areas 141, such that end portions of the corresponding well area 141 respectively located at two opposite sides of the gate part 200A are exposed.

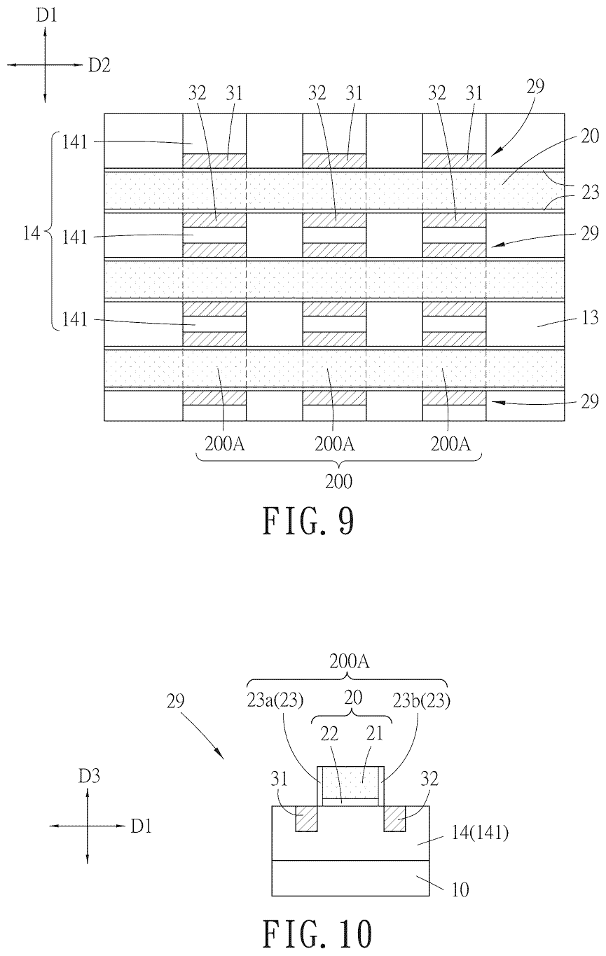

Referring to FIG. 1 and the example illustrated in FIGS. 9 and 10, the method proceeds to step 106, where a source portion 31 and a drain portion 32 are formed in each of the well areas 141 at two opposite sides of a corresponding one of the gate parts 200A along the first direction (D1) (see also FIG. 7). FIG. 9 is a schematic top view of a resultant structure of step 106. FIG. 10 is a cross-sectional view of the resultant structure of step 106 (subsequent to that shown in FIG. 8). After step 106, a plurality of the transistors 29 (one of which is shown in FIG. 10) are obtained, and each of the transistors 29 includes the source portion 31 and the drain portion 32 formed in a corresponding one of the well areas 141, and a corresponding one of the gate parts 200A. Please note that dimension(s) of each of the source and drain portions 31, 32 may be varied according to practical needs. Although the transistor 29 shown in FIG. 10 is configured as a planar field effect transistor (FET), in other embodiments, the transistor may be configured as a fin-type field effect transistor (FinFET), a gate-all-around field effect transistor (GAAFET), or other suitable configurations.

As shown in FIG. 10, in some embodiments, the source portion 31 is formed in the corresponding well area 141 outward of the gate spacer 23a, and the drain portion 32 is formed in the corresponding well area 141 outward of the gate spacer 23b.

In some embodiments, the source portion 31 and the drain portion 32 are formed by performing a second ion implantation process on the two exposed end portions (exposed from the corresponding gate part 200A) of each of the well areas 141. In some other embodiments, the second ion implantation process may also be performed on the entire well regions 14. As shown in FIG. 10, in some embodiments, the source portion 31 and the drain portion 32 are formed extending from an upper surface of the corresponding well area 141 (one of which is shown) into interior of the corresponding well area 141.

In certain embodiments, the source portion 31 and the drain portion 32 have a second conductivity type which is different form the first conductivity type (of the well regions 14). For instance, when the transistors 29 are NMOS transistors, the source portion 31 and the drain portion 32 may be n-type; when the transistors 29 are PMOS transistors, the source portion 31 and the drain portion 32 may be p-type. Types and/or amount of dopants, and/or working conditions of the second ion implantation process may be adjusted according to practical needs. In some embodiments not shown, the source portion 31 and the drain portion 32 may each have a lightly doped region beneath the gate spacer 23a or 23b, and a heavily doped region exposed from the corresponding gate part 200A.

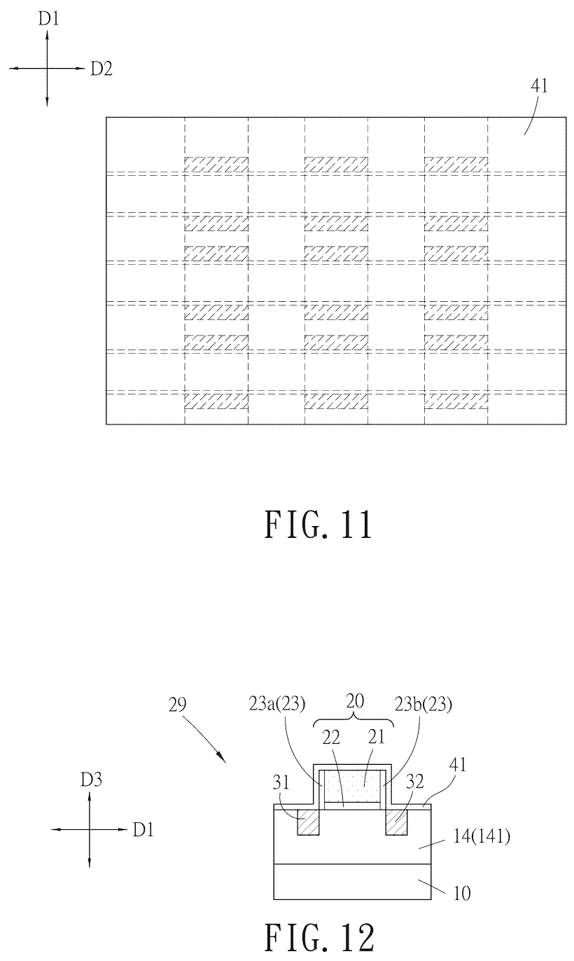

Referring to FIG. 1 and the example illustrated in FIGS. 11 and 12, the method proceeds to step 107, where a protection layer 41 is formed over the structure shown in FIG. 9. FIG. 11 is a schematic top view of a resultant structure of step 106. FIG. 12 is a cross-sectional view of the resultant structure of step 107 (subsequent to that shown in FIG. 10).

In some embodiments, the protection layer 41 is a resist protection oxide (RPO) including oxides, such as silicon oxide, or the like, or combinations thereof, but are not limited thereto. In certain embodiments, the protection layer 41 may be formed using any suitable deposition method, such as chemical vapor deposition (CVD), atomic layered deposition (ALD), or the likes, or combinations thereof, but are not limited thereto. Other suitable materials and/or processes for forming the protection layer 41 are within the contemplated scope of the present disclosure.

In certain embodiments, the protection layer 41 is formed in a conformal manner. The protection layer 41 may be formed to cover the well regions 14, the isolation elements 13 and the transistors 29 (see FIG. 9). In some embodiments, the protection layer 41 covers sidewalls of the gate spacers 23 that are distal from a corresponding one of the gate structures 20 and top surfaces of the gate spacers 23, and cover top surfaces of the gate electrode 21, the source portion 31 and the drain portion 32 of each transistor 29. The protection layer 41 may have a thickness ranging from about 200 nm to about 900 nm. The thickness of the protection layer 41 may be varied according to practical needs and product designs.

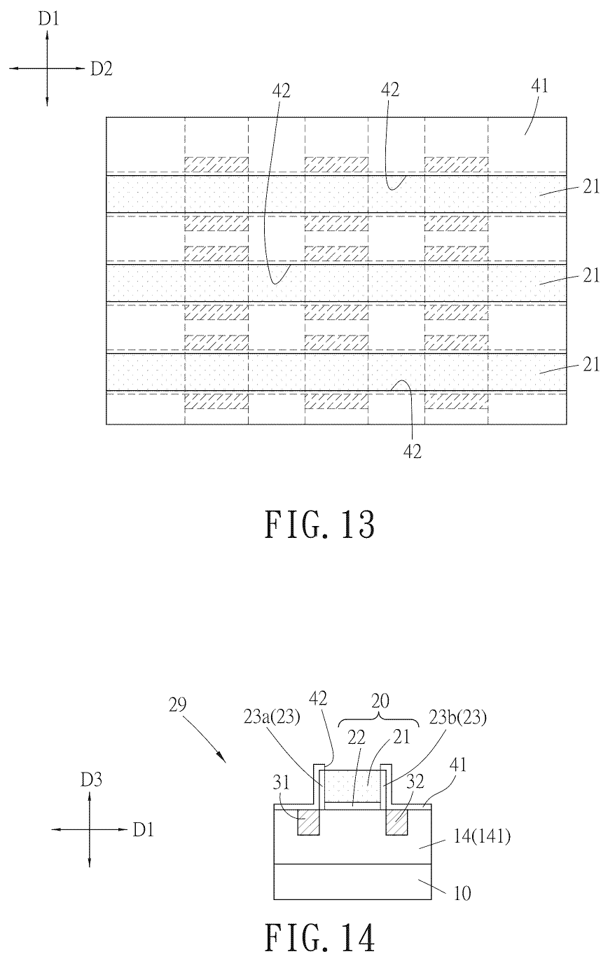

Referring to FIG. 1 and the example illustrated in FIGS. 13 and 14, the method proceeds to step 108, where the protection layer 41 is patterned to form openings 42 to expose the gate structures 20. FIG. 13 is a schematic top view of a resultant structure of step 108. FIG. 14 is a cross-sectional view of the resultant structure of step 108 (subsequent to that shown in FIG. 12).

Step 108 aims to form the openings 42 in the protection layer 41 to expose any predetermined elements that are to be subjected to a silicidation process performed in subsequent step, while other elements that are not intended to undergo the silicidation process remained to be covered by the protection layer 41.

In some embodiments of the present disclosure, the openings 42 respectively expose top surfaces of the gate structures 20, or more specifically, top surfaces of the gate electrodes 21; while the source portion 31 and the drain portion 32 of each of the transistors 29, the well regions 14, the isolation elements 13 (see also FIG. 9) and sidewalls and top surfaces of the gate spacers 23 remain covered by the patterned protection layer 41.

The patterning process may be performed using any suitable processes. In some embodiments, the patterning process may include a photolithography process involving an etching process such as dry etching, but is not limited thereto. Other suitable processes for patterning the protection layer 41 are within the contemplated scope of the present disclosure.

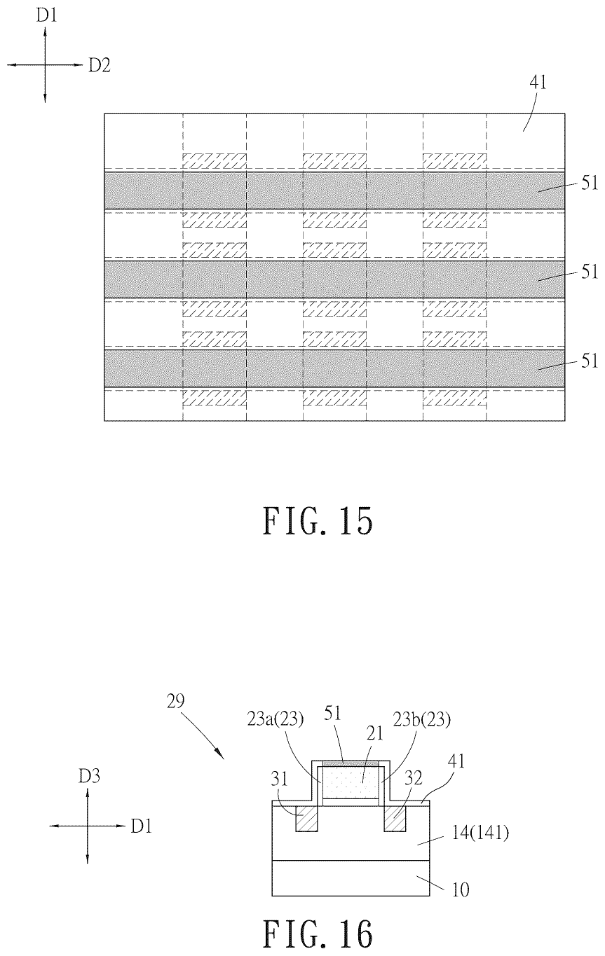

Referring to FIG. 1 and the example illustrated in FIGS. 15 and 16, the method proceeds to step 109, where a silicidation process is performed to form silicide layer(s) 51. FIG. 15 is a schematic top view of a resultant structure of step 109. FIG. 16 is a cross-sectional view of the resultant structure of step 109 (subsequent to that shown in FIG. 14).

In some embodiments, the silicidation process may include depositing a metal layer (not shown) over the structure shown in FIG. 13, followed by performing a thermal treatment (e.g., an annealing process, but is not limited thereto).

In the metal deposition process, the exposed gate electrodes 21 are directly in contact with the deposited metal layer, while the other elements that are covered by the patterned protection layer 41 are not in contact with the metal layer.

In the thermal treatment, metal atoms in the metal layer diffuse to and react with any silicon-based semiconductor material, but are less likely to react with silicon-based dielectric material. Therefore, for portions of the metal layer disposed at the exposed polysilicon gate electrodes 21, metal atoms therein react with silicon atoms in the exposed polysilicon gate electrodes 21 so as to form the silicide layers 51 (i.e., metal silicide). Alternatively, the thermal treatment may be replaced by any other suitable processes that allow the metal atoms to react with the silicon-based semiconductor material. There are no limitations on the materials and working conditions on the deposition process and the thermal treatment, and one may adjust the material and conditions according to practical needs. In addition, the patterned protection layer 41 made of, e.g., silicon dioxide, does not react with the metal atoms in the metal layer, and serves as a silicide blocking layer to prevent the metal atoms from diffusing therethrough and reacting with the elements covered by the patterned protection layer 41. Thus, the elements covered by the patterned protection layer 41, e.g., the source portion 31 and the drain portion 32 of each of the transistors 29, the well regions 14, and the patterned substrate 10 that are made of silicon, are protected and prevented from being silicided, and silicide layers 51 are not formed on these elements. After the thermal treatment, the silicide layers 51 are formed. In some embodiments, each of the silicide layers 51 is formed to fully cover a top surface of a corresponding one of the gate electrodes 21. Thereafter, a non-reacted part of the metal layer is removed.

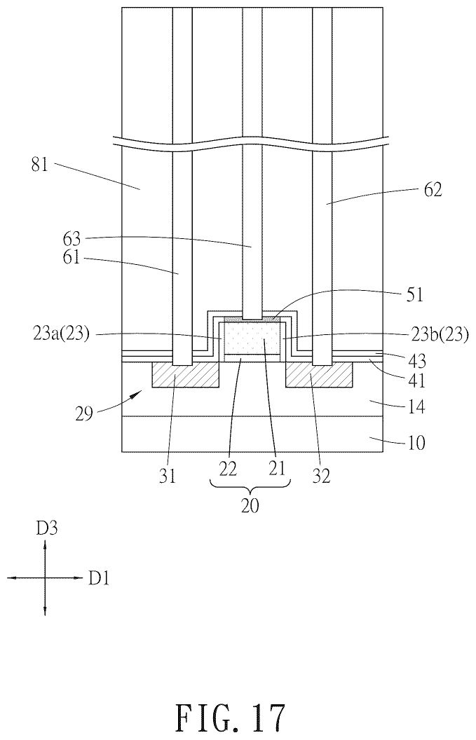

Referring to FIG. 1 and the example illustrated in FIG. 17, the method proceeds to step 110, where source contacts 61, drain contacts 62, and gate contacts 63 are formed in a lower part 81 of an interlayer dielectric (ILD) 80 (see FIG. 18). FIG. 17 is a cross-sectional view of the resultant structure of step 110 (subsequent to and similar to that shown in FIG. 16, except that widths of the source and drain portions 31, 32 shown in FIG. 17 are adjusted) showing one of the source contacts 61, one of the drain contacts 62, and one of the gate contacts 63 that are respectively connected to a corresponding one of the transistors 29.

Step 110 may include: forming an etch stop layer (ESL) 43 and the lower part 81, patterning the lower part 81 and the ESL 43 to form openings (not shown), depositing contact materials (not shown) for forming the contacts 61, 62, 63, and removing an excess amount of the contact materials.

Each of the ESL 43 and the lower part 81 may be formed using any suitable deposition process, such as CVD, ALD, or the likes, or combinations thereof. Each of the ESL 43 and the lower part 71 may include any suitable dielectric material, but the ESL 43 and the lower part 71 are made of different dielectric materials. In some embodiments, the ESL is made of silicon nitride, while the lower part 71 is made of silicon oxide.

The patterning process may be performed using a suitable photolithography process involving a suitable etching process. The openings exposing the source portion 31 and the drain portion 32 of each of the transistors 29 are formed penetrating into the lower part 81, and through the ESL 43 and the protection layer 41. In certain embodiments, the opening exposing the source portion 31 may further extend from an upper surface of the source portion 31 into interior of the source portion 31, and the opening exposing the drain portion 32 may extend from an upper surface of the drain portion 32 into interior of the drain portion 32. In certain embodiments, the opening exposing the silicide layer 51 is formed penetrating into the lower part 81, through the ESL 43 and into the silicide layer 51 without exposing the corresponding gate electrode 21. In some embodiments, the openings exposing the source portion 31, the drain portion 32 and the silicide layer 51 are formed using the same patterning mask and formed at the same time, in which the ESL 43 helps control etching of the aforementioned elements.

In some embodiments, when the source contacts 61, the drain contacts 62 and the gate contacts 63 are made of the same material, a contact material for forming the contacts 61, 62, 63 may be deposited over the lower part 71 and filling the openings at the same time. In other embodiments, the contact materials for forming the contacts 61, 62, 63 may be deposited at different time. The contact materials may include cobalt, ruthenium, tungsten, molybdenum, or the likes, or combinations thereof. Other suitable contact materials for the contacts 61, 62, 63 are within the contemplated scope of the present disclosure.

In some embodiments, removal of the excess amount of the contact materials may be performed using a planarization process such as CMP process, but is not limited thereto. Other suitable processes for forming the source contacts 61, the drain contacts 62 and the gate contacts 63 are within the contemplated scope of the present disclosure.

By completing step 110, the source contacts 61 and the drain contacts 62 are each formed to penetrate the ESL 43 and the protection layer 41, and further extend into the interior of a corresponding one of the source portions 31 and the drain portions 32, i.e., the source contacts 61 and the drain contacts 62 are directly connected to the corresponding one of the source portions 31 and the drain portions 32. The gate contacts 63 are each formed to penetrate the ESL 43 and further extend into the interior of a corresponding one of the silicide layers 51, i.e., the gate contacts 63 are each connected to a corresponding one of the gate electrodes 21 through the corresponding one of the silicide layers 51.

Referring to FIG. 1 and the example illustrated in FIG. 18, the method proceeds to step 111, where memory devices 79, and a back-end interconnect structure including metal lines, vias, via features are formed in an upper part 82 of the ILD 80. FIG. 18 is a cross-sectional view of the resultant structure of step 111 (subsequent to that shown in FIG. 17), showing one of the memory devices 79 connected to a corresponding one of the transistors 29 through corresponding ones of the metal lines (e.g., M11, M12, M13, M21, M22, M23, M31, M32, M4, M5), the vias (e.g., V11, V12, V13, V21, V22, V4), and the via featrues (e.g., a lower via feature V31, and an upper via feature V32).

The back-end interconnect structure is configured to connect different parts of the transistors 29 to predetermined components. For instance, for each of the transistors 29, the source portion 31 is connected to a source line (SL) through the source contact 61, the metal lines (M11, M21) and the via (V11). The gate electrode 21 is connected to a word line (WL) through the silicide layer 51, the gate contact 63, the metal lines (M12, M22, M31), and the vias (V12, V21). The drain portion 32 is connected to the memory device 79 through the drain contact 62, the metal lines (M13, M23, M32), vias (V13, V22) and the lower via feature V31. The memory device 79 is further connected to a bit line (BL) through the metal lines (M4, M5) and the upper via feature V32 and the via (V4). Please note that number of metal lines, number of vias, and configurations of the interconnect structure may be determined according to practical needs.

In some embodiments, the metal lines, the vias, and the via features may include material similar to those of the source contact 61, the drain contact 62, and the gate contact 63, and are not repeated for the sake of brevity. Other suitable materials for forming the metal lines, the vias and the via features are within the contemplated scope of the present disclosure. The back-end interconnect structure may be formed using multiple dual damascene processes, or multiple single damascene processes, or any other suitable processes, or combinations thereof. Other suitable materials and/or processes for the back-end interconnect structure are within the contemplated scope of the present disclosure.

The memory device 79 may include two electrodes 71 and a resistive layer 72 interposed between the two electrodes 71. In some embodiments, the two electrodes 71 may each include a conducting material, e.g., copper, aluminum, tungsten, tantalum, titanium, compounds thereof (e.g., titanium nitride or tantalum nitride), or the likes, or combinations thereof. In some embodiments, the resistive layer 72 may include a dielectric material such as a high dielectric constant (high K) material, but is not limited thereto. Other suitable materials for forming the electrodes 71 and the resistive layer 72 are within the contemplated scope of the present disclosure. In some embodiments, the memory device 79 may further include any other additional suitable elements according to practical needs. In certain embodiments, the memory device 79 is a resistive random-access memory (RRAM) device, but is not limited thereto.

The memory device 79 is formed after formation of the lower via V31 and prior to the upper via V32. The memory device 79 may be formed by sequential formation of an electrode material layer (for forming the electrode 71 connected to the lower via V31), a resistive material layer (for forming the resistive layer 72), and another electrode material layer (for forming the electrode 71 connected to the upper via V32), followed by a patterning process (e.g., an etching process, but is not limited thereto). Other suitable processes for forming the memory device 79 are within the contemplated scope of the present disclosure.

The RRAM device may switch between high resistance state and low resistance state by applying a voltage pulse across the RRAM device. Such switching performance of the RRAM device is controlled by the logic device, i.e, the transistor 29. That is, the switching performance of the RRAM device depends on the performance of the transistor 29.

In the present disclosure, preparation of each of the transistors 29 involves formation of the silicide layer 51 merely on the gate electrode 21, but not on the source portion 31 nor the drain portion 32. That is, the silicide layer is absent between the source portion 31 and the source contact 61 and is also absent between the drain portion 32 and the drain contact 62, and such absence of the silicide layer at these sites may be referred as the non-silicide contact. In the case of silicide contact (i.e., silicide layer is formed between the source portion and the source contact and also between the drain portion and the drain contact), current leakage between the source portion and the drain portion within the same transistor, or with the source portion and/or the drain portion of an adjacent transistor may be observed, and silicide piping might also occur, resulting in contact short, which are undesirable to the performance of the transistor, and indirectly affect performance of the RRAM device. In addition, in order to avoid the current leakage, the transistor and/or the RRAM device are packed in a low density manner, which is unconducive in terms of size shrinkage of a resultant final product. In comparison with a transistor formed with the silicide contact, current leakage in the transistor 29 of the present disclosure, which is formed with the non-silicide contact, may be effectively reduced to better control switching performance of the RRAM device, and to allow the transistor 29 and/or the RRAM device to be more densely packed. In addition, the transistor 29 of the present disclosure, which is formed with the non-silicide contact, may have a comparatively higher breakdown voltage, i.e., less likely to be overdriven, and thus may have a higher reliability.

The embodiments of the present disclosure have the following advantageous features. In the patterning process of the protection layer 41, openings are formed to expose the gate electrode 21 of each of the transistors 29, while the source portion 31 and the drain portion 32 of the corresponding transistor 29 remain covered, so as to permit silicide formation only on the exposed gate electrode 21, resulting in the silicide layer 51 being present only on the gate electrode 21, and is absent on the source portion 31 and the drain portion 32. As such, the transistors 29 of the present disclosure may have a significantly reduced current leakage, and thus may have an improved reliability. The transistors 29, and the RRAM devices respectively connected thereto may have improved performance. In addition, the transistors 29 and/or the RRAM devices may be more densely packed.

In accordance with some embodiments of the present disclosure, a method for manufacturing a semiconductor structure includes: forming a gate structure on a substrate; forming a source portion and a drain portion in the substrate respectively at two opposite sides of the gate structure; forming a protection layer over the substrate, the gate structure, the source portion and the drain portion; forming an opening in the protective layer to expose the gate structure; and performing a silicidation process to form a silicide layer on the exposed gate structure.

In accordance with some embodiments of the present disclosure, in the silicidation process, the source portion and the drain portion are prevented from being silicided.

In accordance with some embodiments of the present disclosure, the method further includes, prior to forming the source portion and the drain portion, forming a well region extending from a top surface of the substrate into an interior of the substrate, the source portion and the drain portion being formed in the well region.

In accordance with some embodiments of the present disclosure, the well region is formed with a first conductivity type, and the source portion and the drain portion are formed with a second conductivity type different from the first conductivity type.

In accordance with some embodiments of the present disclosure, the source portion and the drain portion are formed at two opposite sides of the gate structure along a first direction, respectively, prior to forming the patterned protection layer, the method further includes forming two gate spacers at opposite sidewalls of the gate structure along the first direction.

In accordance with some embodiments of the present disclosure, in forming the patterned protection layer, the patterned protection layer is formed to cover sidewalls of the two gate spacers distal from the gate structure, and to cover top surfaces of the two gate spacers.

In accordance with some embodiments of the present disclosure, the method further includes forming a source contact and a drain contact, each of which penetrates the protection layer and each of which is directly connected to a respective one of the source portion and the drain portion; and forming a gate contact connected to the gate structure through the silicide layer.

In accordance with some embodiments of the present disclosure, the method further includes forming a memory device connected to the drain portion through the drain contact.

In accordance with some embodiments of the present disclosure, the memory device is a resistive random-access memory device.

In accordance with some embodiments of the present disclosure, a method for manufacturing a semiconductor structure includes: forming a gate structure on a substrate; forming a source portion and a drain portion in the substrate respectively at two opposite sides of the gate structure; forming a patterned protection layer that covers the source portion and the drain portion, and that exposes the gate structure; and performing a silicidation process to form a silicide layer on the exposed gate structure.

In accordance with some embodiments of the present disclosure, in the silicidation process, the source portion and the drain portion are prevented from being silicided.

In accordance with some embodiments of the present disclosure, the gate structure includes a gate electrode and a gate dielectric disposed to separate the gate electrode from the substrate, the gate electrode being made of polysilicon.

In accordance with some embodiments of the present disclosure, the method further includes: forming a source contact and a drain contact, each of which penetrates the protection layer and each of which is directly connected to a respective one of the source portion and the drain portion; and forming a gate contact connected to the gate structure through the silicide layer.

In accordance with some embodiments of the present disclosure, the method further includes forming a memory device connected to the drain portion through the drain contact.

In accordance with some embodiments of the present disclosure, the memory device is a resistive random-access memory device.

In accordance with some embodiments of the present disclosure, each of the source contact and the drain contact penetrates the protection layer and extends into an interior of a respective one of the source portion and the drain portion.

In accordance with some embodiments of the present disclosure, a semiconductor structure includes a substrate, a transistor, a gate contact, a source contact, a drain contact, and a memory device. The transistor includes a gate structure disposed on the substrate and including a gate electrode and a gate dielectric disposed to separate the gate electrode from the substrate, and a source portion and a drain portion that are formed in the substrate respectively at two opposite sides of the gate structure. The gate contact is connected to the gate electrode through a silicide layer. The source contact and the drain contact are directly connected to the source portion and the drain portion, respectively. The memory device is connected to the transistor through the drain contact.

In accordance with some embodiments of the present disclosure, the memory device is a resistive random-access memory device.

In accordance with some embodiments of the present disclosure, the silicide layer covers the gate electrode.

In accordance with some embodiments of the present disclosure, the gate electrode is made of polysilicon.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a gate structure on a substrate;
forming a source portion and a drain portion in the substrate respectively at two opposite sides of the gate structure;
forming a protection layer over the substrate, the gate structure, the source portion and the drain portion;
forming an opening in the protective layer to expose the gate structure; and
performing a silicidation process to form a silicide layer on the exposed gate structure.

2. The method according to claim 1, wherein in the silicidation process, the source portion and the drain portion are prevented from being silicided.

3. The method according to claim 1, further comprising,
prior to forming the source portion and the drain portion, forming a well region extending from a top surface of the substrate into an interior of the substrate, the source portion and the drain portion being formed in the well region.

4. The method according to claim 3, wherein the well region is formed with a first conductivity type, and the source portion and the drain portion are formed with a second conductivity type different from the first conductivity type.

5. The method according to claim 1,
wherein the source portion and the drain portion are formed at two opposite sides of the gate structure along a first direction, respectively,
prior to forming the patterned protection layer, the method further comprising forming two gate spacers at opposite sidewalls of the gate structure along the first direction.

6. The method according to claim 5, wherein in forming the patterned protection layer, the patterned protection layer is formed to cover sidewalls of the two gate spacers distal from the gate structure, and to cover top surfaces of the two gate spacers.

7. The method according to claim 1, further comprising:
forming a source contact and a drain contact, each of which penetrates the protection layer and each of which is directly connected to a respective one of the source portion and the drain portion; and
forming a gate contact connected to the gate structure through the silicide layer.

8. The method according to claim 7, further comprising forming a memory device connected to the drain portion through the drain contact.

9. The method according to claim 8, wherein the memory device is a resistive random-access memory device.

10. A method for manufacturing a semiconductor structure, comprising:
forming a gate structure on a substrate;
forming a source portion and a drain portion in the substrate respectively at two opposite sides of the gate structure;
forming a patterned protection layer that covers the source portion and the drain portion, and that exposes the gate structure; and
performing a silicidation process to form a silicide layer on the exposed gate structure.

11. The method according to claim 10, wherein in the silicidation process, the source portion and the drain portion are prevented from being silicided.

12. The method according to claim 10, wherein the gate structure includes a gate electrode and a gate dielectric disposed to separate the gate electrode from the substrate, the gate electrode being made of polysilicon.

13. The method according to claim 10, further comprising:
forming a source contact and a drain contact, each of which penetrates the protection layer and each of which is directly connected to a respective one of the source portion and the drain portion; and
forming a gate contact connected to the gate structure through the silicide layer.

14. The method according to claim 13, further comprising forming a memory device connected to the drain portion through the drain contact.

15. The method according to claim 14, wherein the memory device is a resistive random-access memory device.

16. The method according to claim 13, wherein each of the source contact and the drain contact penetrates the protection layer and extends into an interior of a respective one of the source portion and the drain portion.

17. A semiconductor structure, comprising:
a substrate;
a transistor including:
a gate structure disposed on the substrate, and including a gate electrode and a gate dielectric disposed to separate the gate electrode from the substrate, and
a source portion and a drain portion that are formed in the substrate respectively at two opposite sides of the gate structure;
a gate contact connected to the gate electrode through a silicide layer;
a source contact and a drain contact which are directly connected to the source portion and the drain portion, respectively; and
a memory device connected to the transistor through the drain contact.

18. The semiconductor structure according to claim 17, wherein the memory device is a resistive random-access memory device.

19. The semiconductor structure according to claim 17, wherein the silicide layer covers the gate electrode.

20. The semiconductor structure according to claim 17, wherein the gate electrode is made of polysilicon.
